(19) United States
(12) Patent Application Publication
(10) Pub. No.: US 2005/0024955 A1
(43) Pub. Date: Feb. 3, 2005

(54) Non-falsifiable information carrier material, information carrier produced therefrom and test device therefor

(76) Inventor: Joergen Brosow, Plainfield (AT)

Correspondence Address: Friedrich Kueffner, Suite 910, 317 Madison Avenue, New York, NY, 10017, US

(21) Appl. No.: 10/481,928

(22) PCT Filed: Jun. 27, 2001
(86) PCT No.: PCT/EP01/07315

(51) Int. Cl. G11C 7/00

(52) U.S. Cl. 365/200

(57) ABSTRACT

In order to protect against falsification, an information carrier is doped with a photochromic substance. The location of the points (2), wherein the photochromic substance is embedded, is stored in readable form. For authentication purposes, the location of said points (2) is read out optically and compared with the stored information (FIG. 1), whereby a suitable initialization device is used.

The invention concerns a counterfeitproof information carrier material, which comprises a substrate and at least one photochromic substance, which can be converted by light radiation from a first state to at least one second state, which can be spectroscopically distinguished from the first state, as well as an information carrier produced from this material and apparatus for authenticating the information carrier.

Many types of information carriers, for which it is important to ensure against counterfeiting, are already in everyday use. Examples include especially bank notes, checks, or other financial instruments, whose substrate consists of paper, as well as information carriers made of thicker and stronger substrates, such as credit cards, debit cards, personal identification cards, or the like. Therefore, the terms “information carrier material” and “information carrier” are meant to include all types of recordings that must be protected against unauthorized copying.

To prevent the counterfeiting of bank notes, it is already known (GB 2 272 861 A) that an image can be printed on the bank note paper with permanently visible print and with color-changeable photochromic print that is reversible between two states. To verify the authenticity of the bank note, the permanently visible optical image of the bank note is compared with the photochromic image in its two states, which are produced by suitable light radiation. However, the security standard achieved in this way is not satisfactory, because the improved copying methods now available also make this printing technique accessible to counterfeiters.

The objective of the invention is to create an information carrier material with enhanced security against counterfeiting, information carriers produced from this material, and apparatus for authenticating them.

In accordance with the invention, the objective with respect to the information carrier material is achieved by embedding the photochromic substance in the substrate, which is sufficiently transparent to the visible wavelengths that serve to convert the photochromic substance from the first to the second state.

With the information carrier material of the invention, since the photochromic substance is embedded in the substrate, a qualitatively good counterfeiting would require that the counterfeiter produce the substrate doped with the photochromic substance himself or buy it. Production by the counterfeiter himself is practically ruled out by the high technical demands, while purchase is also impossible due to the lack of general availability of special substrates of this type. A counterfeiting attempt involving application of the substance to the surface of the substrate can be easily detected, for example, by optical methods, due to the attendant change in the surface characteristics.

A strongly absorbent or scattering material, preferably paper, cardboard, plastic, or mixtures thereof, often serves as the substrate. Sufficient transparency of the substrate is present, if its transmission is between 0.001% and 80%, and preferably between 0.01% and 30%. The first and second states of the photochromic substance may be especially isomeric states.

If the photochromic states are characterized by thermal long-term stability, which is referred to as bistability, it is possible to convert the information carrier material to a stable, local second state by purposeful light incidence, which means an initialization according to a local pattern of two states. This local pattern can be used especially as a code for information, which can be used to verify authenticity. Although the techniques necessary for this are well known (see, for example, Science, Vol. 245, Aug. 25, 1989, pp. 843-845, American Scientist, Vol. 82, July/August 1994, pp. 348-355, Computer, Vol. 25, November 1992, pp. 56-67), due to the highly developed laser methods that are necessary for this, these techniques cannot be handled by counterfeiters, whereas they can be carried out on a mass-production scale by authorized producers at very low unit cost. An overview of suitable photochromic materials may be found in Chemical Reviews, Vol. 100, No. 5 (May 2000).

In an advantageous refinement, at least one second state can be returned to the first state by light radiation, and the substrate is sufficiently transparent to these visible wavelengths. In this way, it is possible, to erase at least parts of the pattern produced during the initialization, or a pattern recorded separately from it, and to overwrite it with a pattern that corresponds to new information. Depending on the type of photochromic substance that is used, this erasable second state may be the same state as the second state used in the initialization, but it is also possible to use different second states. Due to this overwriting capability, it is thus possible to write additional information on an information carrier produced on the information carrier material, but also to overwrite previous information, i.e., to replace previous information with new information. If an information carrier of this type passes through several inspection stations, and each inspection station applies a corresponding inspection recording, the route of the information carrier through the various inspection stations can be exactly tracked.

The desired properties, especially good optical distinguishability of the two photochromic states, are found especially among the chromoproteins. Preferably, a bacterial chromoprotein is used. A substance that is especially suitable and that has already been scientifically well tested is bacteriorhodopsin. It is well known that this substance can be switched between isomeric states, for example, by one-photon, sequential one-photon, or two-photon processes, in which the substance is illuminated with light in the green spectral region and light in the red spectral region. It is also well known that two thermally stable states are available with the wild type of bacteriorhodopsin and to a greater extent with some variants of bacteriorhodopsin. The first state is the stable resting state b_{R} and the other is the stable P state or Q state, which can be reached via intermediate states (cf. EP 0 655 162 B1 and “Popp et al., Photochemical Conversion of the O-intermediate to 9-cis-retinal-Containing Products in Bacteriorhodopsin Films. Biophys. J., 65 (1993) 1,449-1,459”). In this way, local regions of the bacteriorhodopsin in the substrate can be thermally permanently initialized. The regions that have been switched to the Q state by the initialization appear more optically transparent when illuminated with light in the red spectral region than the other regions that have remained in the b_{R} state. The light-dark pattern obtained in this way thus constitutes a security feature for the information carrier material.

In a further development of the idea of the invention, it is provided that the photochromic substance in the information carrier material is localized on particles. In this case, each embedding location of a carrier particle can be operated as a localized storage element, whose storage state is represented by the given assumed absorption state of the photochromic substance concentrated there. The photochromic material can be localized on the particles by applying it to the surface of the particles or enclosing it in their volume. It is also possible for the particles themselves to be composed of the photochromic substance(s), possibly with the addition of suitable aids.

In an advantageous embodiment, the photochromic substance is enclosed in particles or hollow particles embedded in the substrate, and the matrix or wall of these particles surrounding the substance is sufficiently transparent to the visible wavelengths used to convert from the first to the second state and to the visible wavelengths used to distinguish the two states. In this connection, the photochromic substance is protected by its inclusion within the hollow particles. In particular, optimum conditions can be established for the photochromic substance within the hollow particles, for example, their moisture content. Moreover, the optical properties of the matrix or wall can be optimized with respect to the optical processes of light absorption during the initialization and illumination with light during the reading and possibly during the erasing of the states, e.g., low light scattering and high optical transparency of the matrix material.

In an important embodiment, the substrate is a paper. This paper is preferably used for the production of bank notes, checks, and all other types of financial instruments.

In accordance with the invention, an information carrier produced from the information carrier material of the invention is characterized by the fact that the substance that has been converted to the second state is localized in at least one point of the information carrier.

The localized conversion of the photochromic substance to its second state can be effected as an initialization step either on the information carrier material or on the information carrier produced from it. In both cases, the local position of this point or these points can be detected in a subsequent optical scanning process, and in this way the authenticity of the information carrier can be verified.

In an advantageous refinement of the invention, it is further provided that position information representing the local position of the point(s) in the information carrier be recorded in readable form on the information carrier. This position information can be recorded on the information carrier, for example, in the form of printed position information data, or it can be recorded by storing it in a readable electronic memory that is inseparably connected with the information carrier. In an authentication process, the recorded position information can then be read, and the information defined by the pattern of the points existing in the second state can be scanned, and the two sets of information can be related with each other. A method for the three-dimensional storage of information with the use of bacteriorhodopsin is specified in U.S. Pat. No. 5,559,732. Of course, it is by no means suggested there that the bacteriorhodopsin is embedded in a matrix with only limited light transmission. There is no provision for writing three-dimensional information into the information carrier claimed there.

In the important case of designing the information carrier as a security, for example, as a bank note, besides printing, storage in a memory circuit provided in the security is basically well known (see DE 196 30 648 A1 and EP 0 905 657 A1).

Devices provided in accordance with the invention for verifying or writing an information carrier in accordance with the invention are specified in claims 9 to 11.

In the description that follows, the invention is explained in greater detail with reference to an embodiment of a bank note illustrated in the drawings.

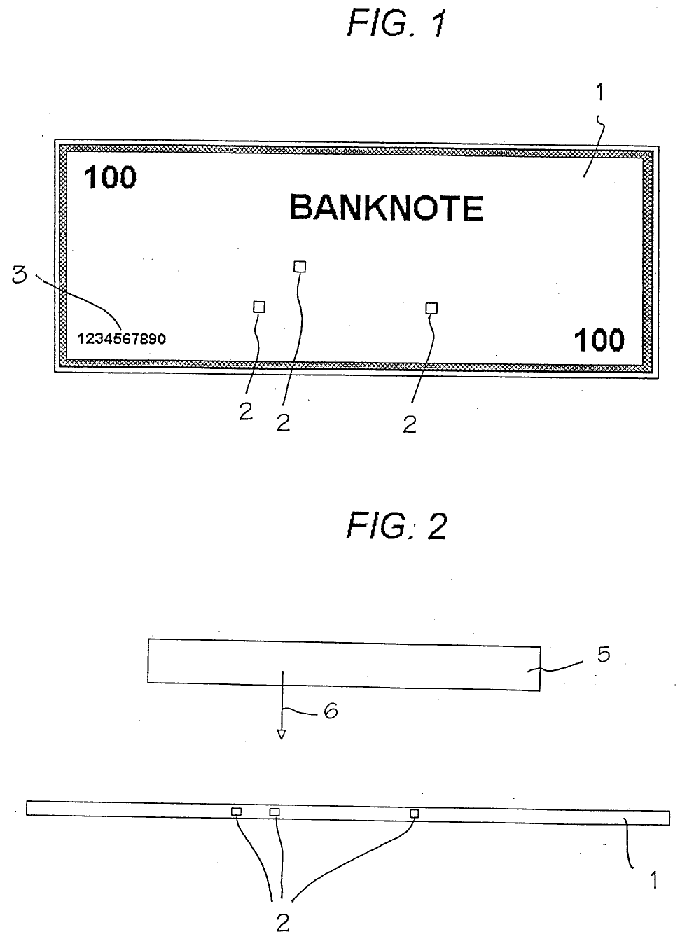

FIG. 1 shows a top view of a bank note.

FIG. 2 shows a cross section perpendicular to the view shown in FIG. 1 with a schematic representation of the light path during the authentication process.

The bank note shown in FIG. 1 consists of a bank note paper that was doped during its production with a photochromic substance, which in the illustrated embodiment is bacteriorhodopsin. The doping can be accomplished, for example, by adding the bacteriorhodopsin to the pulp used to produce the bank note paper, before the paper is formed on the wire. In this case, the banknote has an essentially uniform doping density over its entire surface. Alternatively, the doping can be carried out in such a way that the pulp spread on the wire is doped only in certain places, so that the bank note paper and the bank note 1 have localized surface regions, which may be distributed over the whole surface either uniformly or irregularly. Preferably, the photochromic substance is not introduced into the paper pulp directly, but rather is introduced in the form of carrier particles that contain the substance. The carrier particles are preferably formed as small hollow particles, in which the photochromic substance is enclosed and thus protected from the surrounding paper pulp. The doping of the bank note paper and the bank note 1 is generally invisible to the naked eye.

If the photochromic substance does not have two thermally stable states, but rather returns to the resting state without the action of light, then the presence of the embedded photochromic substance, either in distributed form or bound in or on particles, can be used as a security feature. In the case of bacteriorhodopsin, the resting state, which is designated b_{R}, and the M state, which can be produced by illumination with light in the green or yellow-red spectral region, are suitable for this purpose. The transient generation of bacteriorhodopsin in the M state can be detected with blue light, preferably in the spectral region of 400-415 nm.

If the photochromic substance has the property that it has at least two states with long-term thermal stability, such that it can be converted from one state to the other by the absorption of light, then information can also be introduced into the information carrier material. In the case of bacteriorhodopsin, the resting state, which is designated b_{R}, and the Q state, which can be obtained by illumination with light in the green spectral region and with light in the red spectral region, are suitable for this purpose. In these spectral regions, the paper material is sufficiently transparent to radiation. Therefore, if the bank note paper or the bank note 1 is passed through a laser system that emits suitable light beams, localized points can be converted to the Q state. These points, which are invisible to the naked eye, are indicated by borders in FIGS. 1 and 2. While the schematic representation of FIGS. 1 and 2 show just three such points, any desired number of these points that is ≧1 can be provided in any desired local arrangement.

In connection with the initialization of the bank note 1 effected by the creation of the points 2 that have the Q state, the local positions of these points 2, i.e., their space coordinates on the bank note 1, are determined at the same time, and this position is recorded on the bank note 1. The recording can be made, for example, in the form of an uncoded or coded imprint 3 on the banknote 1, which, for example, can be optically read. In FIG. 1, this imprint is illustrated by the example of a sequence of decimal numerals.

The points 2 formed by the initialization are optically distinguishable from the uninitialized remaining area of the bank note 1. In the case of bacteriorhodopsin, the Q state that exists at the points 2 can be distinguished from the b_{R} state that surrounds the points 2 by illuminating the bank note with low-intensity light in the red spectral region, which is absorbed only by the bR state and not by the Q state. In this reading operation, the points 2 appear more transparent to the light than the area surrounding them. The resulting light-dark pattern can be scanned in this way, and the position information for the points 2 can be read from this pattern.

In FIG. 2, a device 5 suitable for this purpose is indicated schematically. An arrow 6 indicates the direction of the radiated light used for writing or reading. In FIG. 2, the green and red light beams required in the case of bacteriorhodopsin irradiate the same side of the bank note 1. Alternatively, however, it is possible, for example, to illuminate the area of the lower side of the bank note 1 in FIG. 2 with the green light, while the red light is beamed onto the upper surface of the bank note 1 in the form of a focused scanning beam. During this operation, the bank note 1 is moved transversely to the direction of this scanning beam in a scanning motion. The same thing applies to the blue light for the detection of the M state, if two states with long-term thermal stability do not exist in the bacteriorhodopsin.

The position information that characterizes the points 2 is reconstructed in the device 5 from the scanning results. At the same time, the device 5 reads the position information recorded on the bank note 1. The authenticity of the bank note 1 can be verified by comparing the reconstructed and recorded position information.

A device designed according to the diagram in FIG. 2 can also be used for initialization, i.e., for the initial writing of the bank note 1 or for subsequent writing with additional information after previously recorded information has been erased. The initialization is performed by directing light in the green and red spectral regions in the direction of arrow 6, as is necessary for effecting the conversion from the b_{R}, resting state to the Q state. To erase the Q state, light in the blue spectral region is directed in the direction of arrow 6, which converts the Q state back to the b_{R} state. The erased regions can be rewritten.

The reading, writing and erasing operations described above as examples make it possible, very generally, to authenticate the identity of the information carrier material and, in special embodiments, to use it as a data store for recording binary-coded information. To this end, a predetermined grid pattern of recording points is assigned to the information carrier material, and either the first or the second state of the photochromic substance is produced at these points. The two possible states at these recording points reproduce the two binary values “O and 1”. For security, a key can be formed from the recorded bit pattern and, for example, imprinted in optically readable form on the surface of the information carrier or stored in an electronic circuit embedded in the information carrier. In the case of paper, the grid pattern of the recording points is two-dimensional, whereas in the case of spatially extended information carriers, it may be three-dimensional.

### List of Reference Numbers

bank note
points
imprint
authentication apparatus
arrow

1. Counterfeitproof information carrier material, which comprises a substrate and at least one photochromic substance, which can be converted by light radiation from a first state to at least one second state, which can be spectroscopically distinguished from the first state, wherein the photochromic substance is embedded in the substrate, and the substrate is sufficiently transparent to the visible wavelengths that serve to convert the photochromic substance from the first to the second state.

2. Counterfeitproof information carrier material in accordance with claim 1, wherein at least one second state can be converted back to the first state by light radiation, and the substrate is sufficiently transparent to these wavelengths.

3. Counterfeitproof information carrier material in accordance with claim 1, wherein the photochromic material is a bistable material.

4. Counterfeitproof information carrier material in accordance with claim 1, wherein the photochromic substance is a chromoprotein.

5. Counterfeitproof information carrier material in accordance with claim 1, wherein the photochromic substance in the information carrier material is localized on particles.

6. Counterfeitproof information carrier material in accordance with claim 1, wherein the substrate is a paper.

7. Information carrier produced from a counterfeitproof information carrier material in accordance with claim 1, wherein the substance that has been converted to the second state is localized in at least one point (2) of the information carrier (1)

8. Information carrier in accordance with claim 7, wherein position information representing the local position of the point (2) in the information carrier is recorded in readable form on the information carrier.

9. Apparatus for authenticating an information carrier in accordance with claim 7, wherein a device (5), which emits a scanning light beam (6) with a wavelength suitable for distinguishing the second state, for detecting the local positions of the points (2) on the information carrier that have the second state, a device (5) that analyzes the position information corresponding to these points (2), and optionally, a device (5) for reading position information recorded on the information carrier (1) and a device (5) for comparing the detected and the recorded position information.

10. Apparatus for writing an information carrier in accordance with claim 7, wherein a device that emits a writing light beam for converting the photochromic substance from a first to a second state and, optionally, a device that emits an erasing light beam for converting a second state to a first state.

11. Method for writing an information carrier produced from an information carrier material in accordance with claim 1 with binary-coded information, wherein the two binary values “0” and “1” are recorded by the two states of the photochromic substance in a predetermined grid pattern.
